(19) United States
(12) Patent Application Publication
(10) Pub. No.: US 2020/0375069 A1
(43) Pub. Date: Nov. 26, 2020

(54) HIGH PRESSURE HEAT DISSIPATION APPARATUS FOR POWER SEMICONDUCTOR DEVICES

(71) Applicants: Yoatian Zhang, San Dimas, CA (US); George R. Woody, Anaheim, CA (US); Hung-Li Chang, Chino Hills, CA (US); Paul F. Carosa, Covina, CA (US); Ramiro R. Montalvo, San Dimas, CA (US)

(72) Inventors: Yoatian Zhang, San Dimas, CA (US); George R. Woody, Anaheim, CA (US); Hung-Li Chang, Chino Hills, CA (US); Paul F. Carosa, Covina, CA (US); Ramiro R. Montalvo, San Dimas, CA (US)

(21) Appl. No.: 16/391,250

(22) Filed: Apr. 22, 2019

(51) Int. Cl. H05K 7/20; H01L 25/07

(52) U.S. Cl. CPC H05K 7/20927; H01L 25/072

(57) ABSTRACT

An improved power semiconductor heat dissipation apparatus for regulating the temperature of multiple power semiconductors featuring increased structural integrity for high pressure applications, a more robust heat exchange fin design to accommodate particulates or other solid contaminants that may be present in less refined coolant fluids, and a modified construction for increased durability and ease of automated assembly.

### FIELD OF THE PRESENT DISCLOSURE

This disclosure relates generally to an improved heat dissipation apparatus for power semiconductor devices, and more specifically to a heat dissipation apparatus featuring increased structural integrity for accommodating higher pressure applications, more robust heat exchange fin design to better accommodate physical containments in coolant fluids, and a modified construction for increased durability and ease of assembly.

### BACKGROUND OF THE RELATED ART

In any apparatus that contains power semiconductor devices, such as switches or rectifiers, heat dissipation is a critical issue. Excessive heat can lead to deterioration of both physical and electrical properties which in turn can cause both intermittent and permanent failures. Even within tolerable heat ranges, cooler operating temperatures are almost always desirable because cooler operating temperatures typically lead to increased electrical efficiency which, depending on the performance demands on a particular device, may allow a device to operate longer, consume less power, tolerate or endure higher power, or even be redesigned to be made physically smaller. In some fields of technology these advantages are of critical importance so even marginal increases in heat dissipation efficiency may be of great importance.

To achieve lower operating temperatures, power semiconductor devices are typically coupled with a heat sink or a heat dissipation device of some variety. The most efficient heat dissipation devices typically involve a thermally conductive material in physical contact or in close physical proximity to a power semiconductor device which is capable of drawing heat out of a power semiconductor device and transferring the heat energy away from its source for dispersion or dissipation in a more convenient location or at a more convenient rate. Some of the most effective heat dissipation devices achieve this end through the use of liquid coolants.

U.S. Pat. No. 9,443,786 (“the '786 patent”) describes a liquid-cooled heat dissipation device that features a heat exchange surface (such as a serpentine fin) in thermal communication with one or more power semiconductor devices via thermally conductive plates. The heat exchange surface or serpentine fin(s) are situated between an upper and lower plenum within a manifold that features an influent and an effluent located proximate the opposing distal ends of the manifold such that cooling fluid that enters the manifold must travel the length of the manifold before exiting. The '786 patent is incorporated by reference in its entirety into this specification, including the abstract, entire specification, drawings, and claims.

In the heat dissipation apparatus disclosed in the '786 patent, cooling fluid is allowed to enter the apparatus through an influent that feeds into a first plenum and exits the apparatus through an effluent that draws from a second plenum. In order to pass through the apparatus, coolant fluid must flow from the first plenum to the second plenum across the heat exchange surface. Heat energy generated in the power semiconductor devices flows from the point of generation to the heat exchange surface and is then transferred into the passing cooling fluid and is carried out through the apparatus' effluent for ultimate dissipation elsewhere.

Soon after the design disclosed in the '786 patent was developed it became apparent that the thermal efficiency of the design could be further improved by more precisely controlling the cooling fluid pressure to ensure uniform flow distribution across the heat exchange, or, in some applications, to create intentionally non-uniform flow distributions. This was achieved by introducing flow balancers which were disclosed and claimed in U.S. patent application Ser. No. 15/787,711 (“the '711 application”). The '711 application is incorporated by reference in its entirety into this specification, including the abstract, entire specification, drawings, and claims.

The apparatus disclosed in the '711 application is a definite improvement over the apparatus disclosed in the '786 patent; however, there still exists room for further improvement. One area in need of improvement, is the pressure strength of the overall apparatus. Both the previous embodiments utilized an direct bonded copper (“DBC”) backed by epoxy laminate substrate for mounting the power semiconductor devices and for the structural integrity of the walls of the devices. Therefore, the maximum operational coolant fluid pressure in the legacy apparatuses is a function of the strength of the epoxy laminate substrate, both in terms of maximum breaking strength and its overall fatigue endurance. In some applications the use of epoxy laminate substrate for structural integrity is not suffice because the cooling fluid is either maintained at relatively high pressures or because the coolant pressure regularly fluctuates. To maintain structural integrity in such applications, there exists a need for design improvements to the legacy designs to increase structural integrity.

Another area in which the legacy designs could be improved is in their ability to accommodate cooling fluids that contain particulates and other unwanted solid contaminates. In legacy devices, when cooling fluids that contain particulates and other unwanted solid contaminates are used such contaminates progressively get trapped between the serpentine fins of the heat exchange surface causing pressure to build and flow and thermal efficiency to decline. There exists a need for design improvements to the heat exchange surface to increase pass-through of particulate or other unwanted solid contaminates in the coolant fluid.

One further area in which improvement can and should be made is in the ease of assembly. The legacy designs feature a bifurcated manifold that is held together with an anterior and a posterior clip. The installation of the clips are challenging to automate and are, therefore, often secured manually which is not relatively cost effective. There exists a need to modify the legacy designs to improve the ease of automated assembly to reduce manufacturing cost.

The present disclosure distinguishes over the related art providing heretofore unknown advantages as described in the following summary.

### BRIEF SUMMARY OF THE INVENTION

The present disclosure describes an innovative high pressure heat dissipation apparatus for power semiconductor devices. Improving upon the legacy designs disclosed in the '786 patent and the '711 application, the presently disclosed apparatus features design modifications that increase the structural integrity of the apparatus allowing it to accommodate higher pressure coolant fluid applications, increase the ease with which the apparatus may be assembled thereby reducing manufacturing costs, and increase the ease with which the apparatus can accommodate cooling fluids containing particulates and other solid contaminants without experiencing performance declines associated with particulate build-up.

Similar to the apparatus disclosed in both the '786 patent and the '711 application, the presently disclosed apparatus includes a manifold with an influent that leads to a first plenum and effluent that draws from a second plenum and a heat exchange surface located within the manifold between the first and second plenum such that coolant fluid must flow across the heat exchange surface to flow through the apparatus.

However, unlike the legacy designs in which the power semiconductor devices are attached to a direct bond copper (DBC) substrate that is backed by an epoxy laminate material, such as FR-4, the presently disclosed embodiment comprises at least one power semiconductor device attached to a DBC substrate that is sintered or vacuum soldered directly to a copper plate, or if electrical isolation is not necessary the power semiconductor device(s) can be sintered or vacuum soldered directly to the copper plate. Due to the favorable thermal properties of copper, this configuration shows a 1.5% lower steady state device temperature and improved heat spreading when compared legacy designs in testing.

The copper plate on which the power semiconductor device(s) are mounted, either via a DBC substrate or directly, also serves as the structural wall of the manifold. The purpose of this configuration is to significantly increase the structural integrity of the manifold so that it can accommodate significantly higher coolant fluid pressures. In laboratory testing, the improved design performed well for extended periods of time with coolant pressures of at least 400 kPa, both under static pressure and during pressure cycling. Legacy designs featuring epoxy laminate substrates such as FR-4 are typically rated for use with cooling fluid pressures of approximately 200 kPa, approximately half the pressure the modified design can accommodate. The improved pressure tolerance of the modified design is a significant advantage as it greatly increases the number of real world applications that can utilize the improved heat dissipation apparatus.

The structural design improvements of the presently disclosed apparatus also serve to simplify assembly. The legacy designs disclosed in both the '786 patent and the '711 application feature a manifold that bifurcated lengthwise into two equally shaped halves that are joined during assembly by installing two clips that extend the length of the apparatus manifold, one along the superior surface and one along the inferior surface. Installing the clips has proven to be cumbersome and is difficult to automate so this step of assembly is typically performed manually which is not ideal from the perspective of manufacturing efficiency and cost.

The presently disclosed improved design eliminates the need for the pair of clips. Instead of featuring a bifurcated manifold in need of being joined, the improved design features an open manifold frame without lateral structural walls. Each open lateral side of the manifold frame features a groove along the inferior edge and a molded snap along the superior edge such that the manifold frame can accept and secure a copper plate to serve as a structural wall, thereby forming a fully enclosed and complete manifold.

To assemble the improved design, the inferior edge of the copper plate must merely be placed in the groove along the inferior edge of the manifold frame and the superior edge of the copper plate must be pressed laterally into the molded snap of the superior edge of the manifold frame. The copper plate is then secured as a structural wall of a fully enclosed and complete manifold. A gasket along the edge of the copper plate is used to ensure the manifold is sufficiently sealed with respect to coolant fluid.

With respect to improving assembly and manufactural efficiency, the presently disclosed apparatus also includes additional minor design improvements such as negative temperature coefficient (NTC) thermistors directly soldered to the DBC or copper plate. The advantage this improvement provides is that the soldering process can be automated as opposed to the legacy assembly process involving the manual application of adhesives.

The present disclosure also includes improvements in the heat exchange surface design. The heat exchange surface located between the first and second plenum is typically folded many times, sometimes described as shaped in a serpentine fashion, to maximize the potential surface area in contact and heat exchange with the coolant fluid as it flows past. However, problems can arise when the heat exchange surface is so tightly folded that solid contaminants in the cooling fluid get trapped in the heat exchange surface creating back pressure and reducing flow. When this happens in practice the thermal efficiency of the apparatus is negatively impacted and could lead to over heating or failure of the power semiconductor devices.

To reduce the possibility of solid contaminants in the cooling fluid from becoming trapped the heat exchange surface, the presently disclosed apparatus has increased the gaps between the heat exchange surface bends to 1 mm. This is an increase from legacy designs that often features 0.3 mm gaps between bends. In some application this more robust design allows for the elimination of a cooling fluid filter thereby reducing the physical footprint of the overall design.

This disclosure teaches certain benefits in construction and use which give rise to the objectives described below:

A primary objective inherent in the above described apparatus and method is to provide advantages not taught by the prior art;

Another objective is to provide a power semiconductor heat dissipation apparatus with increased structural integrity to withstand high pressure coolant fluid applications;

A further objective is to provide a power semiconductor heat dissipation apparatus that allowed for more economical automated assembly;

A still further objective is to provide a power semiconductor heat dissipation apparatus with improved particulate matter pass through to avoid coolant fluid blockage or pressure build-up;

A yet still further objective is to provide a power semiconductor heat dissipation apparatus with more reliable and consistent temperature monitoring,

Other features and advantages of the present invention will become apparent from the following more detailed descriptions, taken in conjunction with the accompanying drawings, which illustrate, by way of example, the principles and features of the presently described apparatus.

### BRIEF DESCRIPTION OF THE SEVERAL VIEWS OF THE DRAWING(S)

The accompanying drawings illustrate various exemplary implementations and are part of the specification. The illustrated implementations are proffered for purposes of example not for purposes of limitation. Illustrated elements will be designated by numbers. Once designated, an element will be identified by the identical number throughout. Illustrated in the accompanying drawing(s) is at least one of the best mode embodiments of the present disclosure. In such drawing(s):

FIG. 1 is a perspective view of an exemplary embodiment of the presently disclosed heat dissipation apparatus.

FIG. 2 is an cross-sectional view of the presently disclosed heat dissipation apparatus illustrating the novel groove and snap design manifold that increases the structural integrity of the apparatus while also increasing ease of assembly automation.

FIG. 3 is an exploded view of the wall of the presently disclosed apparatus illustrating each layer in order from inner most to outermost, the heat exchange surface, copper plate, direct bond copper layer, exemplar power semiconductors, and exemplar thermistors.

FIG. 4 is a perspective view of an exemplary embodiment of the legacy design of the presently disclosed heat dissipation apparatus shown for comparison purposes.

FIG. 5 is a perspective view of an exemplary embodiment of a heat exchange surface featuring 0.3 mm thick heat exchange surface and 1 mm gaps designed to better accommodate particulates and other solid contaminants in the cooling fluid, also featuring louver design to increase dissipation efficiency.

FIG. 6 is a perspective view of an exemplary embodiment a heat exchange surface featuring 0.3 mm heat exchange surface and 1 mm gaps designed to better accommodate particulates and other solid contaminants in the cooling fluid, also featuring a wave design to increase thermal efficiency.

FIG. 7 is a plan view of a plurality of power semiconductor devices depicting a thermistor directly sintered or vacuum soldered on the direct bonded copper substrate which is in turned bonded to a copper plate providing improved structural integrity, thermal spreading, thermal monitoring, and ease of assembly.

FIG. 8 is a plan view of the heat dissipation profile of power semiconductor devices mounted on the presently disclosed construction comprising direct bonded copper substrate bonded to a copper plate, demonstrating better heat dissipation than the legacy design illustrated in FIG. 9 (lighter shades represent higher temperatures).

FIG. 9 is a plan view of the heat dissipation profile of power semiconductor devices mounted on the legacy design construction comprising only direct bonded copper substrate backed by epoxy laminate substrate such as FR-4, demonstrating poorer heat dissipation than the presently disclosed improved design illustrated in FIG. 8 (lighter shades represent higher temperatures).

### DETAILED DESCRIPTION OF THE EXEMPLARY EMBODIMENT

The above described drawing figures illustrate an exemplary embodiment of the presently disclosed apparatus and its many features in at least one of its preferred, best mode embodiments, which is further defined in detail in the following description. Those having ordinary skill in the art may be able to make alterations and modifications to what is described herein without departing from its spirit and scope of the disclosure. Therefore, it must be understood that what is illustrated is set forth only for the purposes of example and that it should not be taken as a limitation in the scope of the present apparatus or its many features.

Described now in detail is a high pressure heat dissipation apparatus featuring fortified structural integrity, increased capacity to pass coolant fluid continents, and an improved design to simplified assembly.

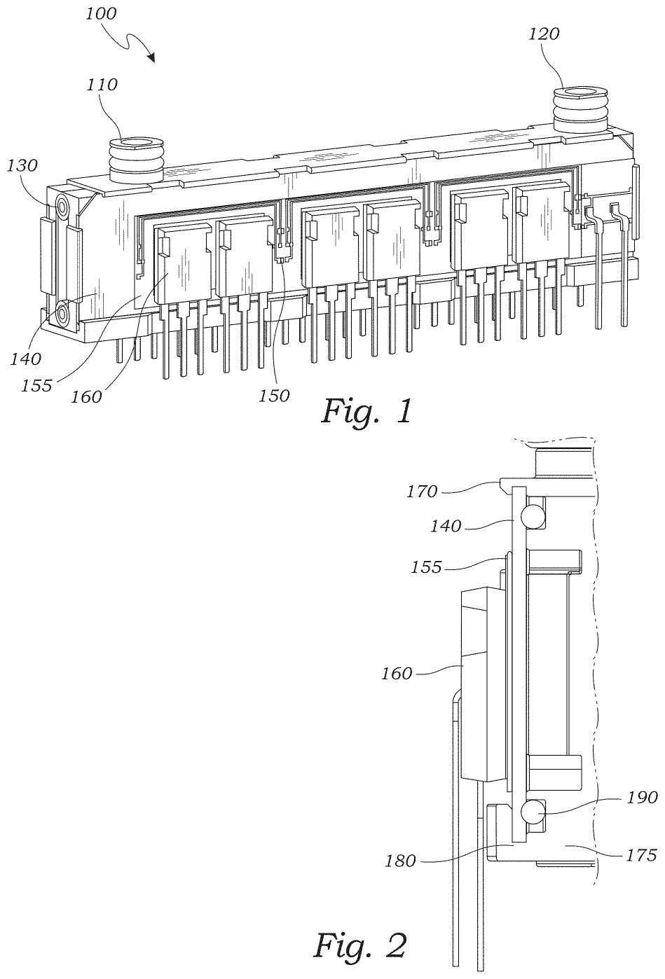

FIG. 1 illustrates an exemplary embodiment of the presently disclosed high pressure power semiconductor heat dissipation apparatus 100 featuring a manifold with an influent 110 for ingress of coolant fluid and an effluent 120 for egress of cooling fluid. FIG. 1 is shown with multiple power semiconductor devices 160 bonded to direct bond copper substrate pads (DBC) 155 to provide the power semiconductor devices 160 electrical isolation. The DBC substrate pads 155 are sintered or vacuum soldered to a copper plate 140. In applications that do not require electrical isolation, power semiconductors can be bonded directly to the copper plate 140.

Regardless of whether DBC substrate 155 is utilized, the copper plate 140 provides greatly improved structural integrity to the apparatus in comparison to legacy designs that utilized epoxy laminate substrate such as FR-4. The improved structural integrity allows the presently disclosed apparatus to accommodate applications that require high pressure cooling fluids. In testing the presently disclosed apparatus demonstrated both static and dynamic operational integrity with cooling fluid pressure of at least 400 kPa.

FIG. 1 also features mechanical mounting points 130 to allow for more robust mounting options and for better vibration tolerance thereby increasing the range of environments the presently disclosed apparatus can endure.

FIG. 2 illustrates a cross-section of the presently disclosed improved apparatus 100 showing a power semiconductor device 160 bonded to a DBC substrate pad 155 which in turn is bonded to a copper plate 140. The angle of the illustration depicts how the copper plate 140 is secured to the manifold frame 175 by a groove 180 along the inferior edge of the manifold frame 175 and a snap 170 along the superior edge of the manifold frame 175. FIG. 2 also depict the gasket 190 that provides a robust seals along the junction between the copper plate 140 and the manifold frame 175.

During assembly, the inferior edge of the copper plate 140 is placed in the grove 180 located along the inferior edge of the manifold frame 175 and then the copper plate 140 is pressed laterally toward the manifold frame 175 until the superior edge of the copper plate 140 is secured by the snap 170 that is molded along the superior edge of the manifold frame 175. This assembly procedure is much simpler than the assembly procedure of legacy designs that involved installing clips 135 shown in FIG. 4, more importantly, the simpler design is possible to automate which can yield significant manufacturing cost savings.

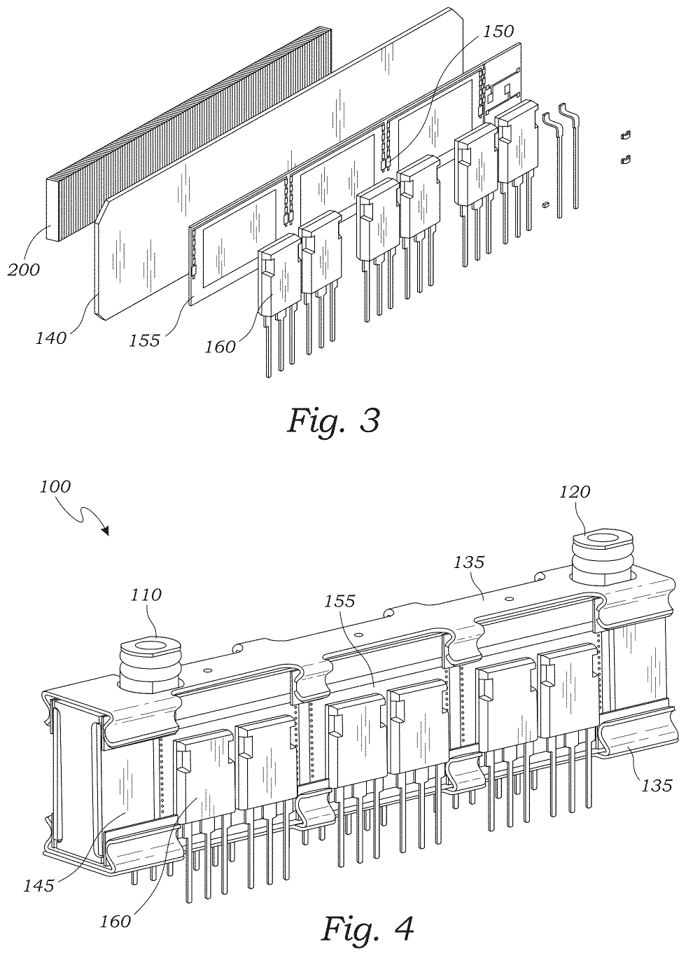

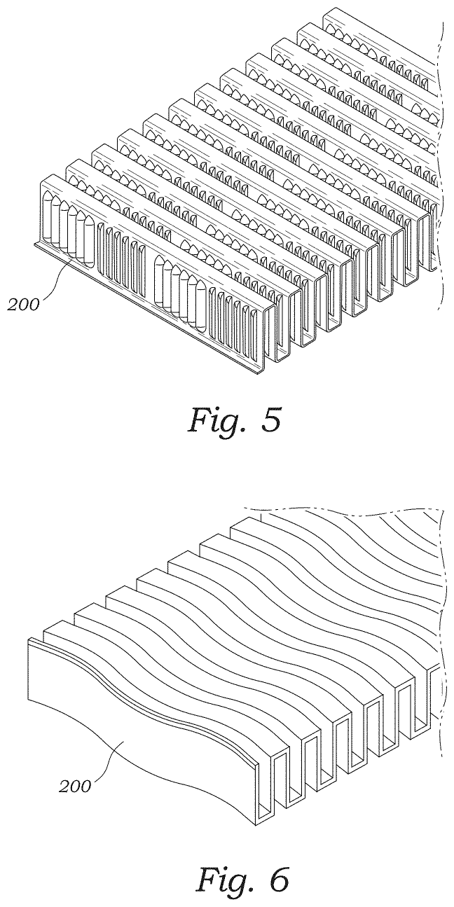

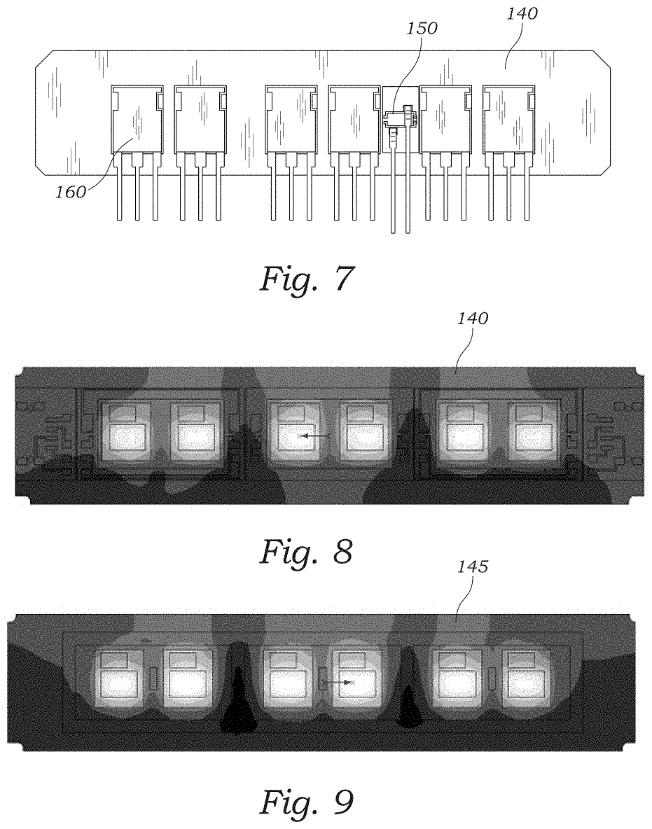

FIG. 3 illustrates an exploded perspective view the heat transfer path between the power semiconductor 160 and the heat transfer surface 200. The illustration shows six power semiconductor 160 devices that are electrically isolated on the DBC substrate pads 155 that are bonded to the copper plate 140 which is in direct thermal contact with the heat transfer surface 200. The illustration also shows multiple NTC thermistors 150 directly soldered to the DBC substrate pad 155 providing one more manufacturing advantage over legacy designs that utilized manual application of adhesives to the secure NTC thermistors 150. Another exemplar configuration illustrating two NTC thermistors soldered directly to a separate DBC substrate pad is depicted in FIG. 7.

FIGS. 8 and 9 illustrate the superior heat spreading performance of the copper plate 140. The illustrations depict testing in which the power semiconductor devices were each operating at 560 ARMS. In FIG. 8 the power semiconductor devices were bonded to DBC substrate pads 155 bonded to a copper plate 140, whereas in FIG. 9 the power semiconductor devices were bonded to DBC substrate pads 155 mounted on legacy epoxy laminate substrate. The superior heat spreading of the improved design in FIG. 8 is visually apparent. The improved design also presented a lower steady state temperature by 1.5%.

The enablements described in detail above are considered novel over the prior art of record and are considered critical to the operation of at least one aspect of the apparatus and its method of use, and to the achievement of the above-described objectives. The words used in this specification to describe the instant embodiments are to be understood not only in the sense of their commonly defined meanings, but to include by special definition in this specification: structure, material, or acts beyond the scope of the commonly defined meanings. Thus, if an element can be understood in the context of this specification as including more than one meaning, then its use must be understood as being generic to all possible meanings supported by the specification and by the word(s) describing the element.

The definitions of the words or drawing elements described herein are meant to include not only the combination of elements which are literally set forth, but all equivalent structures, materials or acts for performing substantially the same function in substantially the same way to obtain substantially the same result. In this sense it is therefore contemplated that an equivalent substitution of two or more elements may be made for any one of the elements described and its various embodiments or that a single element may be substituted for two or more elements in a claim.

Changes from the claimed subject matter as viewed by a person with ordinary skill in the art, now known or later devised, are expressly contemplated as being equivalents within the scope intended and its various embodiments. Therefore, substitutions, now or later known to one with ordinary skill in the art, are defined to be within the scope of the defined elements. This disclosure is thus meant to be understood to include what is specifically illustrated and described above, what is conceptually equivalent, what can be obviously substituted, and also what incorporates the essential ideas.

The scope of this description is to be interpreted only in conjunction with the appended claims and it is made clear, here, that each named inventor believes that the claimed subject matter is what is intended to be patented.

What is claimed is:

1. An improved power semiconductor heat dissipation apparatus, said apparatus comprising:
a liquid heat exchange manifold comprising:
a first and second plenum;
an influent allowing cooling fluid ingress to said manifold to said first plenum;
an effluent allowing cooling fluid egress from said manifold from said second plenum; and
at least one copper plate having an internal and external surface;
a heat exchange surface in thermal communication with said internal surface of said copper plate;
at least one power semiconductor in thermal communication with said external surface of said copper plate;
wherein said heat exchange surface is situated within said manifold between said first plenum and said second plenum such that cooling liquid much pass through said heat exchange surface to flow from said first plenum to said second plenum;
wherein said copper plate is a structural member that defines said manifold, which is capable of withstanding coolant fluid pressure up to at least 400 kPa.

2. An apparatus as in claim 1 wherein said heat exchange surface is a thermally conductive material with a thickness of no more than 0.3 mm featuring a plurality of serpentine folds with a gap of at least 1 mm between each folds to allow coolant fluid flow.

3. An apparatus as in claim 1 further including a plurality of power semiconductor devices, wherein said power semiconductor devices are electrically isolated from each other by a direct bond copper substrate;

4. An apparatus as in claim 1 further including at least one thermistor in thermal communication with said copper plate.
